(19) United States
(12) Patent Application Publication
(10) Pub. No.: US 2019/0139788 A1
(43) Pub. Date: May 9, 2019

(54) APPARATUS AND METHODS FOR PACKAGING SEMICONDUCTOR DIES

(71) Applicant: Applied Materials, Inc., Santa Clara, CA (US)

(72) Inventors: Boyi FU, San Jose, CA (US); Han-Wen CHEN, Cupertino, CA (US); Kyuil CHO, Santa Clara, CA (US); Sivapackia GANAPATHIAPPAN, Los Altos, CA (US); Roman GOUK, San Jose, CA (US); Steven VERHAVERBEKE, San Francisco, CA (US); Nag B. PATIBANDLA, Pleasanton, CA (US); Yan ZHAO, Santa Clara, CA (US); Hou T. NG, San Jose, CA (US); Ankit VORA, San Jose, CA (US); Daihua ZHANG, Los Altos, CA (US)

(73) Assignee: Applied Materials, Inc., Santa Clara, CA (US)

(21) Appl. No.: 16/171,000

(22) Filed: Oct. 25, 2018

Related U.S. Application Data
(60) Provisional application No. 62/581,451, filed on Nov. 3, 2017.

(51) Int. Cl. H01L 21/56; H01L 21/67

(52) U.S. Cl. CPC H01L 21/565; H01L 21/67126; H01L 21/568

(57) ABSTRACT

Aspects of the disclosure generally relate to methods of immobilizing die on a substrate. In one method one or more immobilization features are formed in a selected pattern on a substrate. A die is positioned in contact with the one or more immobilization features and the substrate. The one or more immobilization features are cured, and a mold layer is formed on top of the cured one or more immobilization features and the die so as to encapsulate the die.

### CROSS-REFERENCE TO RELATED APPLICATIONS

This application claims benefit of U.S. Provisional Patent Application Ser. Number 62/581,451, filed Nov. 3, 2017, which is herein incorporated by reference.

### BACKGROUND

### Field

Implementations of the present disclosure generally relate to apparatuses and methods for packaging semiconductor dies on a substrate. More particularly, implementations of the present disclosure relate to apparatuses and methods for die immobilization and molding.

### Description of the Related Art

In semiconductor substrate processing, integrated circuits are formed on a substrate (also referred to as a wafer) composed of silicon or other semiconductor material. In general, layers of various materials which are either semiconducting, conducting or insulating are utilized to form the integrated circuits. These materials are doped, deposited and etched using various processes to form integrated circuits. Each substrate is processed to form a large number of individual regions containing integrated circuits. Each individual region is known as a die and contains integrated circuits to perform a specific function.

Following the integrated circuit formation, the dies may be encapsulated in an encapsulation process as part of an overall packaging process. The encapsulation process is used to encapsulate the dies with a material that prevents physical damage and/or corrosion of the dies. Conventionally, dies are encapsulated using a thermal compression molding process. A molding material may be applied over and around each die on the substrate during the molding process. For example, the molding material may be an epoxy material. After applying the molding material, a setting process may be used to apply heat and pressure to the molding material and the substrate to form and set the molding material with the die disposed in the molding material. One potential problem that may occur during the compound application process and the setting process of the molding process is that one or more die may move on the substrate due to forces applied to the dies during the molding process. Such movement causes alignment issues in later fabrication processes.

There is a need for methods and apparatus for encapsulating dies that minimizes movement of the dies.

### SUMMARY

In one example, a method for packaging a die on a substrate comprises forming one or more immobilization features in a selected pattern on the substrate by inkjet printing; positioning a die in contact with the one or more immobilization features and the substrate; curing the one or more immobilization features; and forming a mold layer on top of the cured one or more immobilization features and the die so as to encapsulate the die.

In another example, a method for packaging a plurality of die on a substrate comprises forming a plurality of immobilization structures on the substrate, wherein each of the plurality of immobilization structures is in a contact position with at least one of the plurality of dies, forming each of the plurality of immobilization structures comprising forming a first immobilization feature on the substrate. Forming the first immobilization feature comprises: dispensing a plurality of first droplets on the substrate; curing the dispensed first droplets to form a first cured layer; forming a second immobilization feature on a surface of the first cured layer, wherein forming the second immobilization feature comprises: dispensing a plurality of second droplets on the first cured layer; and curing the dispensed second droplets to form a second cured layer.

In another example, a method for packaging a die on a substrate comprises positioning a die in contact with the substrate; forming one or more immobilization features in a selected pattern on the substrate and in contact with the die, the one or more immobilization features formed by inkjet printing; curing the one or more immobilization features; and forming a mold layer on top of the cured one or immobilization features and the die.

### BRIEF DESCRIPTION OF THE DRAWINGS

So that the manner in which the above recited features of the present disclosure can be understood in detail, a more particular description of the disclosure, briefly summarized above, may be had by reference to implementations, some of which are illustrated in the appended drawings. It is to be noted, however, that the appended drawings illustrate only exemplary implementations and are therefore not to be considered limiting of scope, as the disclosure may admit to other equally effective implementations.

FIGS. 1A-1B shows schematic cross-sectional views of a substrate having a plurality of dies formed on the substrate during sequential stages of an immobilization process, according to an implementation.

FIGS. 2A-2B shows a schematic top view and a schematic cross-sectional view of one of the dies on the substrate shown in FIG. 1B.

FIGS. 3A-3B shows a schematic top view and a schematic cross-sectional view of one of the dies on the substrate, according to another implementation.

FIGS. 4A-4B shows a schematic top view and a schematic cross-sectional view of one of the dies on the substrate, according to another implementation.

FIGS. 5A-5B shows a schematic top view and a schematic cross-sectional view of a plurality of dies on the substrate, according to another implementation.

FIGS. 6A-6B shows a schematic top view and a schematic cross-sectional view of a plurality of dies on the substrate, according to another implementation.

FIGS. 7A-7D shows schematic cross-sectional views of sequential stages of a molding process performed on a plurality of the dies shown in FIG. 1B.

FIG. 8A is a schematic view of a system for immobilizing dies, according to an implementation.

FIG. 8B is a schematic view of a portion of the system illustrated in FIG. 8A, according to an implementation.

FIG. 9 is a flow chart of an encapsulation process, according to an implementation.

To facilitate understanding, identical reference numerals have been used, where possible, to designate identical elements that are common to the figures. It is contemplated that elements and features of one embodiment may be beneficially incorporated in other implementations without further recitation.

### DETAILED DESCRIPTION

The present disclosure generally relates to methods and apparatus for packaging a plurality of dies, also referred to as dice, on a substrate. The packaging process may include an encapsulation process used to encapsulate the plurality of dies on the substrate to provide protection for the dies. The encapsulation process includes an immobilization process that uses additive printing to form a plurality of immobilization features on the substrate in a selected pattern to minimize movement of the dies during the encapsulation process. Each of the plurality of immobilization features are cured using a curing device providing electromagnetic radiation. The plurality of immobilization features are in the form of immobilization structures that secure the dies on the substrate. In some implementations, the encapsulation process includes a molding process where a mold layer is formed on top of the immobilization features and encapsulates the dies. The immobilization features minimize or eliminate movement of the dies on the substrate, and that limits the material used during the encapsulation process during the packaging process. The resultant encapsulated dies thus may be made more effectively and at a lower cost.

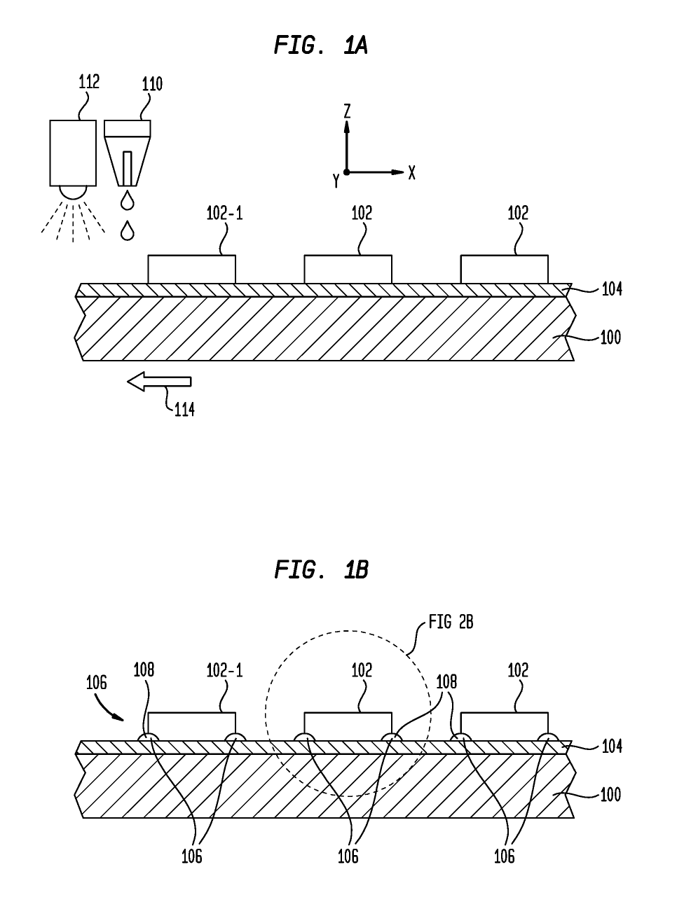

FIGS. 1A-1B illustrate schematic cross-sectional views of a substrate 100 having a plurality of dies 102 formed on the substrate 100 during sequential stages of an immobilization process where each die 102 is immobilized. Each die 102 contains integrated circuits to perform a specific function. The sequential stages for immobilizing the dies 102 are referred to as an immobilization process. The substrate 100 has dies 102 that are preformed and disposed on the substrate 100, as shown in FIG. 1A. The dies 102 are shown formed on the substrate 100 with a contact layer 104 disposed between the substrate 100 and the dies 102. In some implementations, the dies 102 may be formed directly on the substrate 100 without the contact layer 104. The substrate 100 may include one or more dies 102, and may include more than the three dies shown in FIGS. 1A-1B. The contact layer 104 may be in the form of an adhesive layer that adheres to the substrate 100 and the plurality of dies 102. The contact layer 104 is disposed between the dies 102 and the substrate 100.

As shown in FIGS. 1A-1B, a printer 110 is schematically shown disposed over the substrate 100. The printer 110 is an additive manufacturing device. In some implementations, the printer 110 is an inkjet printer. The printer 110 forms a plurality of immobilization features 108 in a selected pattern on the substrate 100. The printer 110 may use one or more droplet ejecting printers for sequentially printing the immobilization features 108 by dispensing droplets. The immobilization materials used to form portions of the immobilization structure 106 may be formed from at least one ink jettable pre-polymer composition that may be a mixture of functional polymers, functional oligomers, reactive diluents, and curing agents to achieve the desired properties of the immobilization structures 106. A curing device 112 is disposed over the substrate 100. The curing device 112 may provide electromagnetic radiation, such as UV (ultraviolet) energy, to cure each of the plurality of immobilization features deposited by the printer 110.

Both the printer 110 and the curing device 112 move relative to the substrate 100 to allow positioning over selected regions of the substrate 100, as depicted by an arrow 114. For example, the substrate 100 may be moved to the left to re-position the printer 110 and curing device 112 to a selected location over the substrate 100. In other implementations, the printer 110 and the curing device 112 may remain stationary relative to the moving substrate 100. Typically, the immobilization features 108 are formed using the printer 110 and curing device 112 controlled by a CAD (computer-aided design) program. The printer 110 and the curing device 112 may move relative to the substrate 100 during the immobilization process that includes a printing process performed by the printer 110 and a curing process performed by the curing device 112.

During the immobilization process, the printer 110 moves over the dies 102 to form the plurality of immobilization features 108. The printer 110 is controlled to form the immobilization features 108 in a selected pattern for the dies 102 formed on the substrate 100. The immobilization features 108 form an immobilization structure 106 which in one example includes immobilization features 108 disposed at the perimeter of each die 102, for example, one immobilization feature 108 at each corner. Each immobilization structure 106 includes one or more immobilization feature 108 that secure at least one of the dies 102. For example, the selected pattern may include an immobilization structure 106 that is at least partially disposed around a die perimeter of one of the dies 102. The selected pattern is pre-designed and the design for the selected pattern is created prior to dispensing immobilization material from the printer 110.

Referring to FIG. 1A, the printer 110 and the curing device 112 is shown disposed above the substrate 100 and adjacent the first die 102-1 prior to forming immobilization structures 106 on the substrate 100 to secure the dies 102. To form the immobilization structures 106, the printer 110 performs the printing process by dispensing a plurality of droplets on the substrate 100 to form a selected pattern for the immobilization features. For example, droplets may be dispensed adjacent to the first die 102-1 onto the substrate 100, as schematically depicted in FIG. 1A, during the immobilization process to form a first immobilization feature disposed adjacent the first die 102-1. The curing device 112 is used to cure the dispensed droplets to form a first cured layer. The printer 110 and the curing device 112 are positioned over multiple locations over the substrate 100 to dispense droplets over selected locations to form the immobilization features 108 for the dies 102.

The printer 110 may be controlled to form a second immobilization feature 108 on the top surface of the first cured immobilization feature 108, or adjacent thereto. More specifically, the printer 110 is controlled to move over the substrate 100 to dispense a plurality of second droplets on the first cured immobilization layer 108. The plurality of second droplets is cured using the curing device 112 as described with respect to the first immobilization feature 108. This feature-by-feature process is repeated to form the plurality of immobilization features 108 that form at least one immobilization structure 106 for each die 102, as shown in FIG. 1B. Each immobilization structure 106 secures at least one of the die 102 in place on the substrate 100. FIG. 1B shows that the immobilization structure 106 for each of the dies 102 is separate from the other immobilization structures 106 for the other dies 102. The immobilization process using the printer 110 and the curing device 112 allows for each die 102 have its own immobilization structure 106 so that the immobilization structures 106 are separate from one another so as to not be in physical contact with one another.

In some implementations, the immobilization structure 106 for each die 102 may have a plurality of immobilization features 108. The printer 110 and curing device 112 may form the immobilization features 108 by first forming one of the immobilization features 108. After forming one of the immobilization features 108, the printer 110 and curing device 112 may be repositioned to produce another immobilization feature 108 having a plurality of. This sequence of forming the immobilization features 108 may be repeated until all of the immobilization features 108 for one of the dies 102 is completed. In other implementations, a first immobilization structure 106 may be formed including multiple immobilization features 108 surrounding one of the die 102, and then a second immobilization structure 106 may be formed on top of the first immobilization structure 106 including the multiple immobilization features 108. FIG. 1B depicts the dies 102 on the substrate 100 with the immobilization structures 106 after the immobilization process has been performed by the printer 110 and curing device 112.

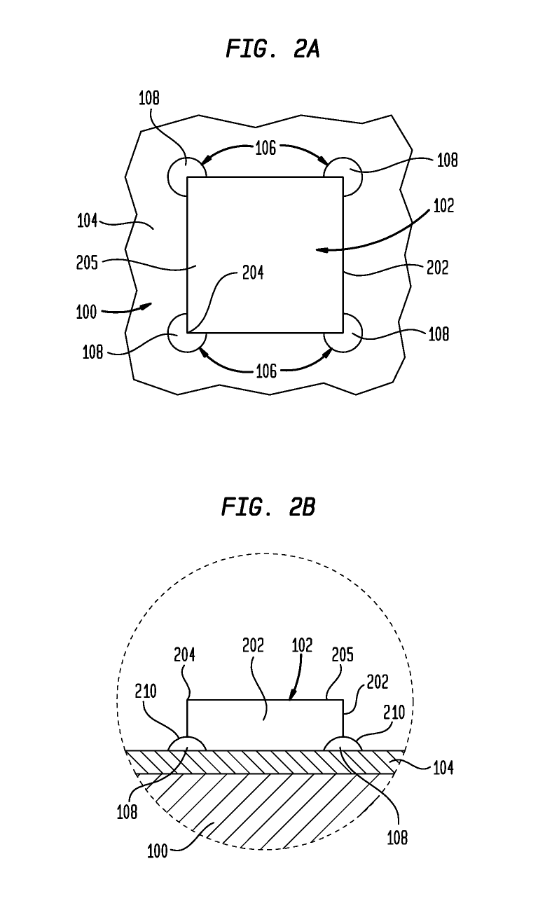

Referring to FIGS. 2A-2B, a die 102 from FIG. 1B is shown having immobilization features 108 on the substrate 100 in a selected pattern around the die 102, according to one implementation. FIG. 2A shows a schematic top view and FIG. 2B is a schematic cross-sectional view of the substrate 100, illustrating one of the dies 102 from FIG. 1B. The selected pattern includes immobilization structure 106 formed by immobilization features 108. The immobilization structure 106 is disposed at least partially around a perimeter of the die 102, as depicted in FIG. 2A. The die 102 is shown to have a rectangular shape and has a plurality of sides 202, a plurality of corners 204, and a top 205. The selected pattern includes a plurality of immobilization features 108 on the substrate 100. Each immobilization structure 106 is formed by the immobilization features 108. The plurality of immobilization features 108 are spaced apart from one another. In the implementation shown in FIGS. 2A-2B, each immobilization feature 108 is positioned at one of the corners 204 of the die 102.

Each of the immobilization features 108 is formed on the substrate 100 in contact with the die 102 as well as contact layer 104 (or the substrate 100 in the absence of a contact layer). Each immobilization feature 108 is in a contact position with the die 102 where at least a portion of each immobilization feature 108 abuts against one of the sides 202 of the die 102. The immobilization features 108 for the die 102 form the selected pattern and secure the die 102 in its original position on the substrate 100. The die 102 is disposed in an original position on the substrate 100 prior to the immobilization process. The immobilization features 108 of the immobilization structure 106 secure the die 102 to the substrate 100 so that the die 102 does not move from the original position or any movement from the original position is minimized during subsequent stages of the encapsulation process or other packaging processes.

Each immobilization structure 106 may have a selected number of immobilization features 108. Different immobilization structures 106 may have a different number of immobilization features 108. The immobilization features 108 of FIG. 2B is shown to extend vertically from the contact layer 104 and partially up the side 202 of the die 102. Each of the immobilization features 108 shown in FIG. 2B has a top surface 210. In some implementations, the top surface 210 may extend up the side 202 up to approximately one third of the vertical height of the side 202, or further. The portion of the side 202 that the immobilization feature 108 extends may be in the range of 10 percent to about 50 percent of a height of the side 202. In some implementations, each immobilization feature 108 for the immobilization structure 206 may be formed by a single droplet dispensed from the printer 110. The feature-by-feature printing process for the immobilization feature has a benefit of limiting the amount of material used for the immobilization structure 106.

The printing process and curing process are adapted to prevent or minimize any movement of the die 102 during the immobilization process. For example, the dispensing of the droplets from the printer 110 on the substrate 100 is adapted to minimize the forces of the dispensed droplets acting on the sides 202 of the die 102. The properties of the droplets, including the composition, size and viscosity of the droplets, are selected to minimize the forces of the dispensed droplets acting on the die 102. In one example, each immobilization feature 108 is separately cured by the curing device 112 and the die 102 is progressively secured in place after each immobilization feature 108 is cured. The curing device 112 cures the dispensed droplets rapidly to secure the die on the substrate 100. In some implementations, the curing device 112 is disposed in a first curing position that is disposed proximate one of the immobilization features 108 for a curing period of between approximately 1-2 seconds. After the curing period is completed, the curing device 112 may be moved to a different curing position proximate another immobilization feature 108 for the die 102.

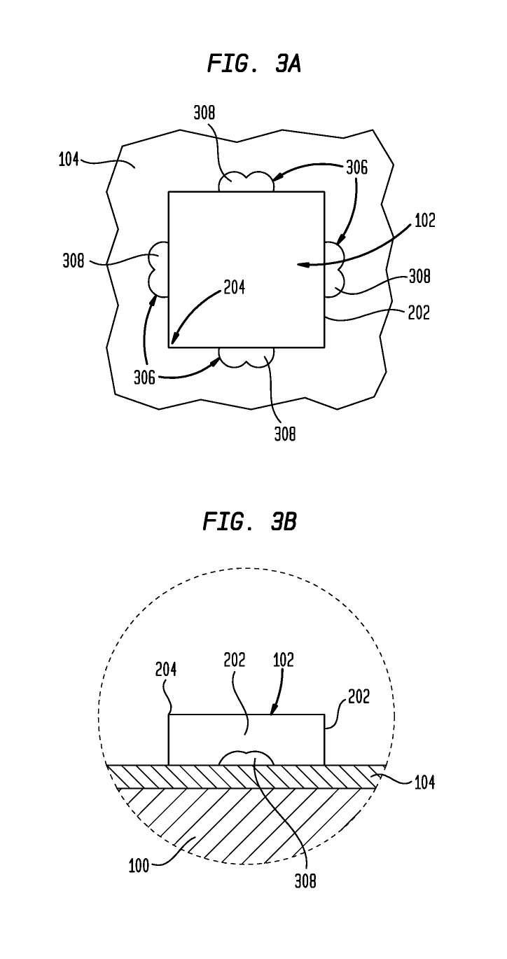

Referring to FIGS. 3A-3B, the die 102 is shown having an immobilization structure 306 in a selected pattern around the die 102, according to an alternative implementation. The immobilization structure 306 includes immobilization features 308 disposed on the sides 202 of the die 102. FIG. 3A is a schematic top view and FIG. 3B is a schematic cross-sectional view of the substrate 100, showing the immobilization features 308 on the substrate 100 in a selected pattern around the die 102. The immobilization features 308 of FIG. 3B are similar to the immobilization features 108 shown in FIGS. 2A-2B but with an alternative selected pattern. The immobilization features 308, as shown in FIG. 3A, may include a first immobilization feature, a second immobilization feature, a third immobilization feature, and a fourth immobilization feature with each of the immobilization features 308 disposed on at least one of the plurality of sides 202 of the die 102, for example, centrally along a respective side 202.

Each immobilization feature 308 is positioned between and spaced apart from the corners 204 of a respective side 202. Each immobilization feature 308 may be formed by dispensing one or more (a pair is shown) of droplets over the substrate 100. In the shown example, a pair of droplets are disposed adjacent one another on the substrate 100 so that the pair of droplets abut one another in a side-by-side position, as shown in FIGS. 3A and 3B, thereby forming a respective immobilization feature 308. In some implementations, each immobilization feature 308 may be formed from one droplet from the printer 110. The vertical height and other aspects of the immobilization structure 306 are similar to the immobilization features 408.

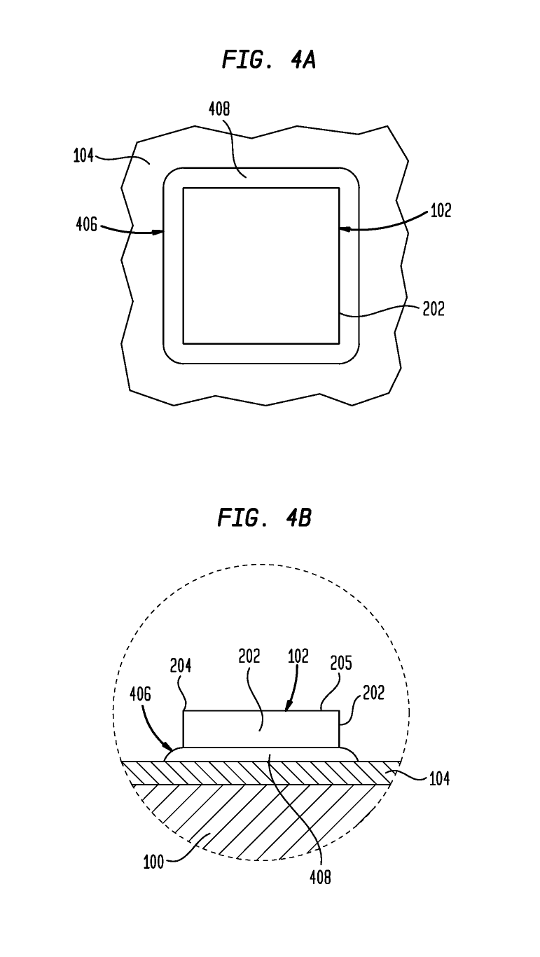

Referring to FIGS. 4A-4B, the die 102 is shown having an immobilization structure 406 on the substrate 100 in a selected pattern around the die 102, according to an alternative implementation. FIG. 4A is a schematic top view and FIG. 4B is a schematic cross-sectional view of the substrate 100, showing the immobilization structure 406 on the substrate 100 in a selected pattern around the die 102. The immobilization structure 406 of FIG. 3B is similar to the immobilization structure 106 shown in FIGS. 2A-2B but with an alternative selected pattern. The immobilization structure 406 has an elongated shape and extends around the perimeter of the die 102. In the implementation shown, the immobilization structure 406 is in the form of an immobilization feature 408 that fully extends around a perimeter of the die 102 to surround the die 102 without interruption. In the implementation shown in FIGS. 4A-4B, the immobilization structure 606 is formed on the contact layer 104 and extends along each side of the die. The vertical height and other aspects of the immobilization structure 406 are similar to the immobilization features 308.

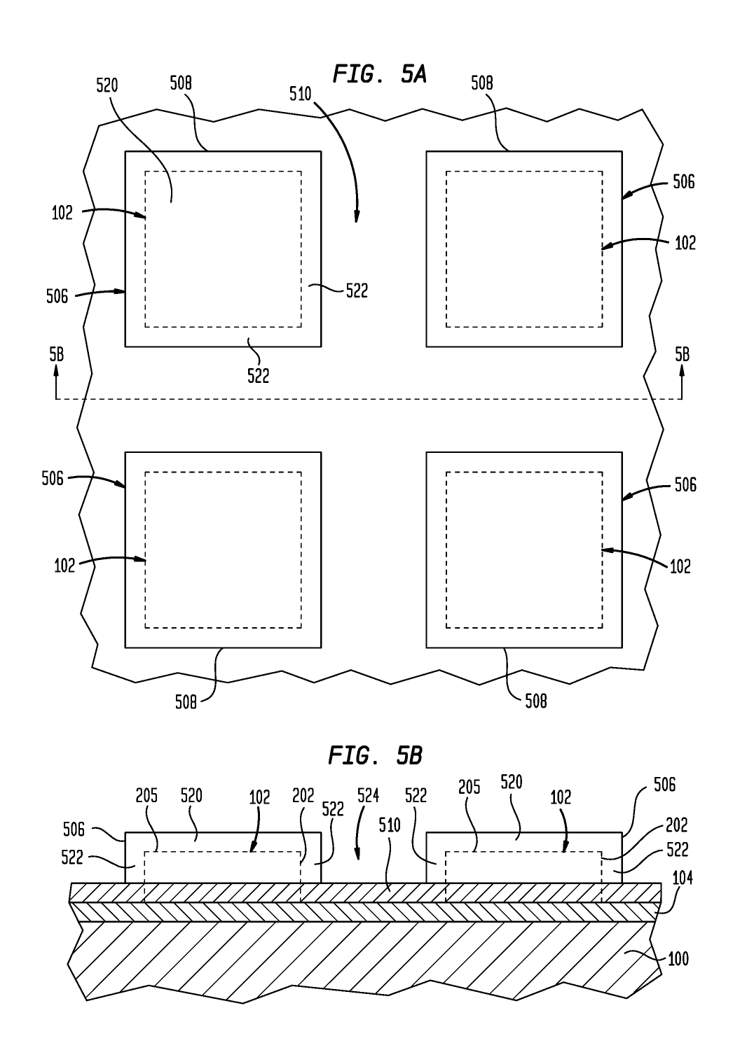

Referring to FIGS. 5A-5B, a plurality of dies 102 is shown having immobilization structures 506 on the substrate 100 in a selected pattern around each of the dies 102, according to an alternative implementation. In this implementation, the immobilization structures 506 encapsulate the dies 102. FIG. 5A is a schematic top view of the plurality of dies 102. FIG. 5B is a schematic cross-sectional view of the substrate 100, showing the die 102 having an immobilization structure 506 and the die 102 having an immobilization structure 506. Each immobilization structure 506 is formed by a single immobilization feature 508.

Each immobilization structure 506 is formed by forming the immobilization structure 506 from the contact layer 104 to the top 205 of each side 202 of the dies 102. Each immobilization structure 506 includes a top member 520 and side members 522. Each top member 520 abuts the top 205 of one of the dies 102. Each side member 522 abuts one of the sides 202 of the dies 102. Together the top members 520 and the side members 522 encapsulate the dies 102.

In some implementations, the immobilization structures 506 extend between die 102 to form an intermediate section 510 that connects immobilization structures 506. The intermediate section 510 may extend from the contact layer 104 to a position below the top 205 of dies 102, as shown in FIG. 5B. An intermediate gap 524 is formed between the side member 522 of adjacent immobilization structures 506 and above the intermediate section 510.

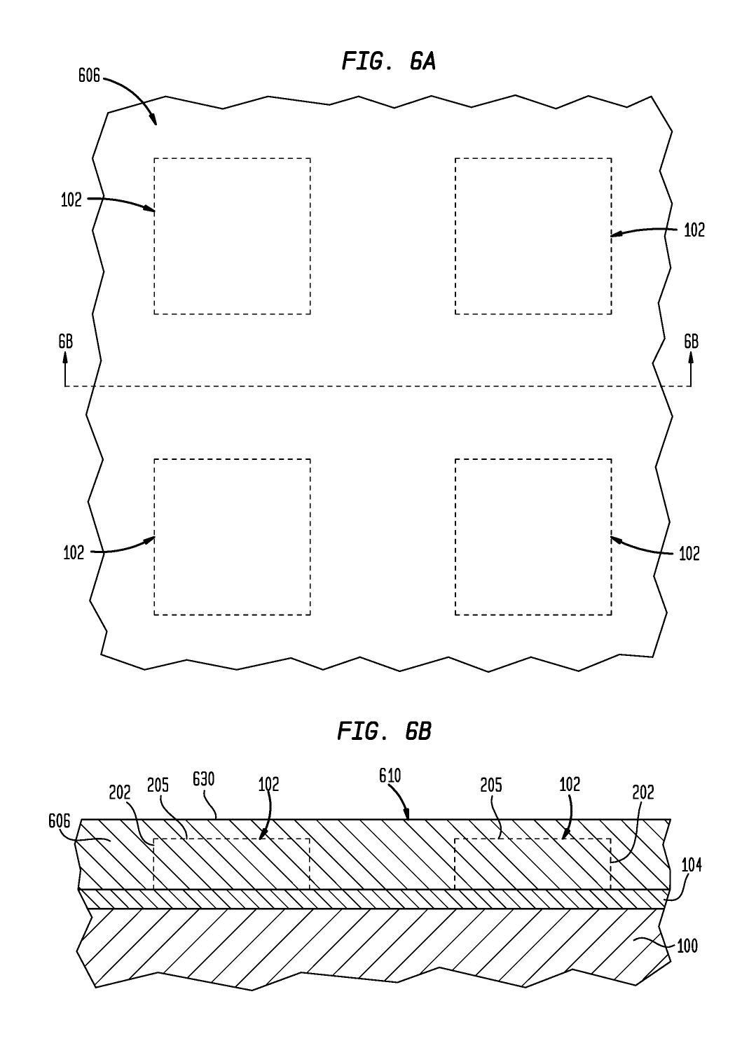

Referring to FIGS. 6A-6B, a plurality of dies 102 is shown having an immobilization structure 606 on the substrate 100 in a selected pattern for immobilizing each of the dies 102, according to an alternative implementation. FIG. 6A is a schematic top view of the immobilization structure 606 encapsulating the dies 102. FIG. 6B is a schematic cross-sectional view of the substrate 100, showing the dies 102 encapsulated by the immobilization structure 606. The immobilization structure 606 is formed by forming the immobilization structure 606 from the contact layer 104 upwards to a top surface 630 disposed above the top 205 of dies 102 so as to encapsulate the dies 102. The immobilization structure 606 is encapsulated during the printing of the immobilization structure 606. The immobilization structure 606 fully encapsulates the dies 102 so that the immobilization structure 606 abuts the sides 202 and the top 205. The immobilization structure 606 is disposed between the dies 102 to form an intermediate section 610. The top surface 630 of the immobilization structure 606 extends over the dies 102 and the portion of the contact layer 104 disposed between the dies 102. The immobilization structure 606 encapsulates the dies 102A and 102B during the immobilization process. As shown in FIG. 6B, the space between dies 102 is filled during the printing process. In the implementation shown, the immobilization structure 606 forms a continuous immobilization structure 606 surrounding the dies 102.

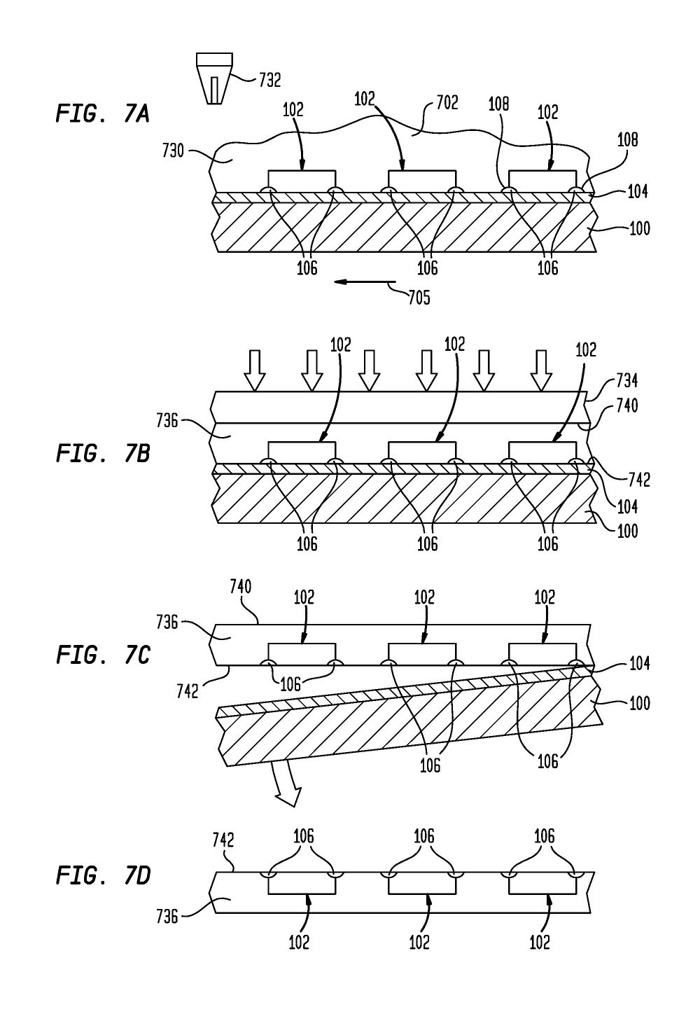

FIGS. 7A-7D illustrates schematic cross-sectional views of sequential stages of a molding process performed on a plurality of the dies 102 after the dies 102 have been immobilized by the immobilization process, as shown for example in FIGS. 1B and 2A-2B. However, the molding process may be performed with other implementations described herein. The encapsulation process may include both the immobilization process and the molding process. After the dies 102 have been immobilized by the immobilization process, a molding material 730 is applied by a molding material dispenser 732 disposed over the substrate 100. The molding material dispenser 703 moves relative to the substrate 100, as depicted by arrow 705, to dispense a molding material 702 onto the substrate 100, onto the dies 102 and onto the immobilization structures 106 to encapsulate the dies 102, as shown in FIG. 7A. When the dies 102 are encapsulated by the molding material 730, the molding material 730 covers the dies 102 and the immobilization structures 106. For example in FIG. 7B, the molding material 730 is in physical contact with the dies 102, the immobilization structures 106, and a top surface of the contact layer 104 so as to form a mold layer. The molding material 702 may be an epoxy material, and may be stored in a mold compound unit (not shown) coupled to the molding material dispenser 703.

After the molding material 702 has been dispensed and encapsulates the dies 102 to form the mold layer, sufficient heat and pressure are applied to the molding material 730 by a mold 734 to form and set the molding material 730, thus forming a molded substrate 736, as shown in FIG. 7B. The molded substrate 736 forms the mold layer. The molded substrate 736 includes a first surface 740 and a second surface 742. It is to be understood that the amount of pressure and the temperature are dependent upon the specific molding material 730 that is selected. The mold 734 may be formed by a mechanical press and heater (not shown) may be used to facilitate setting of the molding material 730. It is also contemplated that a molding material 730 which does not require heat and/or pressure may be utilized.

Referring to FIG. 7C, the substrate 100 and the contact layer 104 are removed from the molded substrate 736. The substrate 100 and the contact layer 104 may be removed, for example, by mechanical separation, or by chemically removing or inactivating the contact layer 104. After the removal of the substrate 100 and the contact layer 104, the molded substrate 736 may be flipped over, as shown in FIG. 7D. The molded substrate 736 may also be cut so that the dies 102 are separated from one another, and the separated dies remain protected by the molded substrate 736.

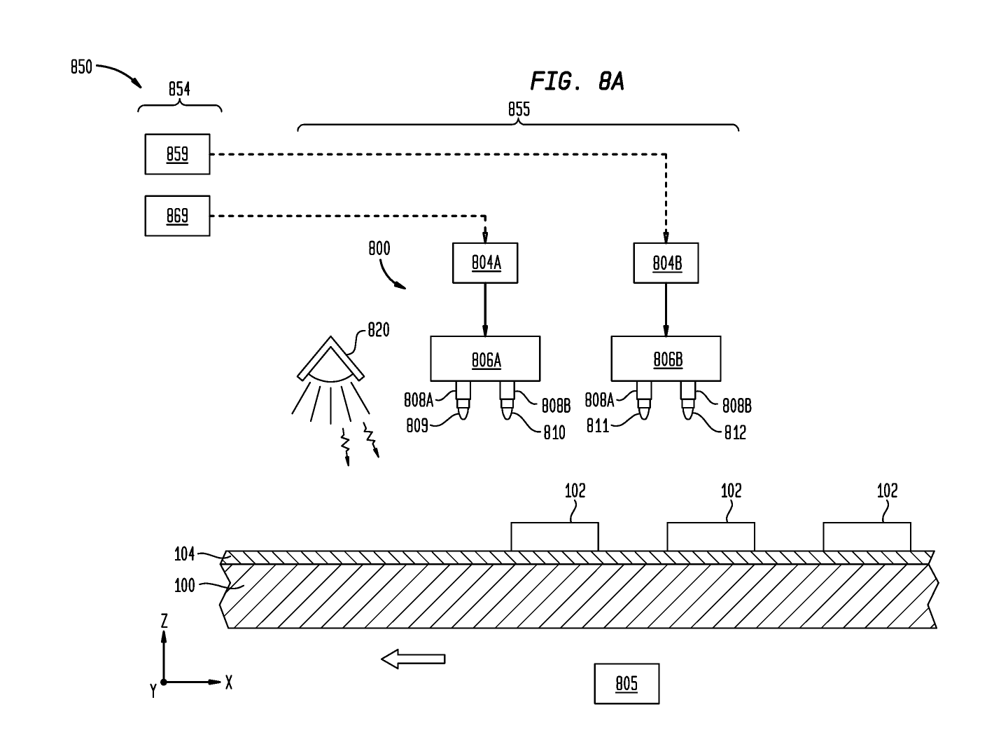

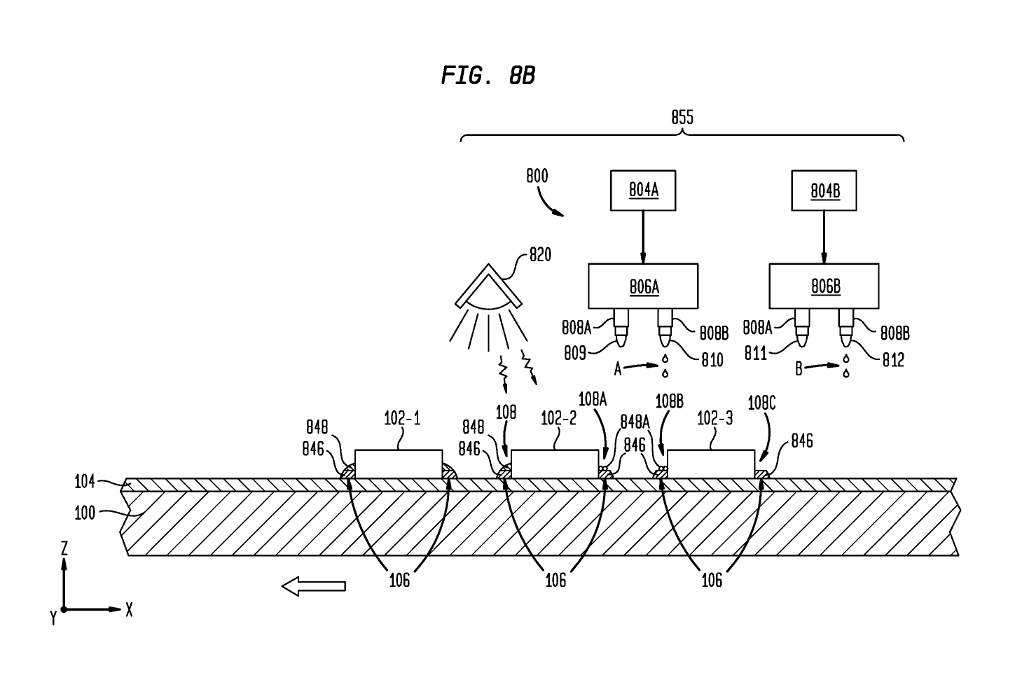

FIG. 8A is a schematic sectional view of an additive manufacturing system 850 that can be used to perform the encapsulation process to form encapsulated dies 102 using an additive manufacturing process according to one or more implementations of the present disclosure. An additive manufacturing process may include, but are not limited to a process, such as a polyjet deposition process, inkjet printing process, fused deposition modeling process, binder jetting process, powder bed fusion process, selective laser sintering process, stereolithography process, vat photopolymerization digital light processing, sheet lamination process, directed energy deposition process, or other similar 3D deposition process. In some implementations, the additive manufacturing system 850 may also be combined with the molding process shown in FIGS. 7A-7D.

The additive manufacturing system 850 generally includes a formulation section 854 and a deposition section 855. The additive manufacturing system 850 may further include a precursor delivery section (not shown). The precursor delivery section (not shown) is used to deliver one or more precursors to the formulation section 854 to form a first printable ink composition 859. The precursor delivery section (not shown) may also be used to deliver one or more precursors to the formulation section 854 to form a second printable ink composition 869. The first printable ink composition 859 and the second printable ink composition 869 may be different compositions, and may be delivered to the deposition section 855 to be used as the immobilization material.

The deposition section 855 includes a printing station 800 and a curing device 820. The printing station 800 functions as an additive manufacturing device. The immobilization structures 106 used to secure the dies 102 may be printed on the substrate 100 by the printing station 800. The printing station 800 includes a printer 806A and a printer 806B that are supplied with a liquid composition by a reservoir 804A and a reservoir 804B, respectively. The reservoirs 804A, 804B may be supplied by the first printable ink composition 859 and the second printable ink composition 869.

The substrate 100 may be supported by a substrate support (not shown). Typically, each immobilization structure 106 is formed layer by layer using one or more printers 806A and 806B illustrated in FIG. 8A, from a CAD (computer-aided design) program. The printers 806A, 806B may be droplet ejecting printers. The printers 806A, 806B and the substrate 100 may move relative to each other during the printing process. FIG. 8B shows the immobilization structure 106, as also described with respect to FIG. 1. However, the additive manufacturing system 850 may be used to form other immobilization structures that have different selected patterns, such as the selected patterns discussed herein.

Each printer 806A, 806B may include one or more print heads 808A, 808B having one or more nozzles 809 (e.g. nozzles 809-812) for dispensing liquid compositions. In the embodiment of FIG. 8A, the printer 806A includes print head 808A that has a nozzle 809 and a print head 808B having a nozzle 810. The nozzles 809, 810 each may be configured to dispense a liquid composition. In some implementations, the printing station 800 may include a single printer 806A and not include additional printer 806B. The liquid composition may be dispensed at selected locations or regions to form the immobilization structures 106 that have desirable properties. These selected locations collectively form the selected pattern that can be stored as a CAD-compatible file that is then read by an electronic controller 805, which controls the delivery of the droplets from the one or more nozzles 809, 810 of the printer 806A.

The controller 805 is generally used to facilitate the control and automation of the components within the additive manufacturing system 850, including the printers 806A, 806B and the curing device 820. The controller 805 also may be used to facilitate the control and automation of the molding material dispenser 703, shown in FIG. 7A. The controller 805 can be, for example, a computer, a programmable logic controller, or an embedded controller. The controller 805 typically includes a central processing unit (CPU) (not shown), memory (not shown), and support circuits for inputs and outputs (I/O) (not shown).

The CPU may be one of any form of computer processors that are used in industrial settings for controlling various system functions, substrate movement, chamber processes, and control support hardware (e.g., sensors, motors, heaters, etc.), and monitor the processes performed in the system. The memory is connected to the CPU, and may be one or more of a readily available non-volatile memory, such as random access memory (RAM), flash memory, read only memory (ROM), floppy disk, hard disk, or any other form of digital storage, local or remote. Software instructions and data can be coded and stored within the memory for instructing the CPU. The support circuits are also connected to the CPU for supporting the processor in a conventional manner. The support circuits may include cache, power supplies, clock circuits, input/output circuitry, subsystems, and the like.

A program (or computer instructions) readable by the controller 805 determines which tasks are performable by the components in the additive manufacturing system 850. Preferably, the program is software readable by the controller 805 that includes code to perform tasks relating to monitoring, execution and control of the deposition section 855. These tasks include the delivery and positioning of droplets delivered from the printer 806A and/or printer 806B, the delivery and positioning of radiation delivered from the curing station over the substrate 100, the delivery and positioning of the molding material 702 from the molding material dispenser 732 and mold 734, and the movement, support, and/or positioning of the components within the printer 806A, 806B along with the various process tasks and various sequences being performed in the controller 805.

The printing station 800 may include one or more curing devices 820, such as the curing device 820 disposed adjacent to the printer 806A, as shown in FIG. 8A. In some implementations, a second curing device (not shown) may be disposed adjacent to the printer 806B. The curing device 820 is disposed within the deposition section 855 of the additive manufacturing system 850. The curing device 820 is used to cure each immobilization feature prior to printing a subsequent immobilization feature on top of the earlier printed immobilization feature. For example, the printer 806A may dispense first droplets onto the substrate 100 to form a first immobilization feature. The curing device 820 may be positioned proximate the printer 806A to cure the dispensed droplets rapidly to form a first cured layer. The printer 806A may dispense second droplets onto the first cured layer to form a second immobilization feature on top of the first cured layer. The curing device 820 may be used to cure the second immobilization feature to form a second cured layer on top of the first cured layer. This process may be repeated to form a plurality of immobilization features.

In an alternative embodiment, the printer 806A and the curing device 820 may be used to print and cure the first immobilization feature to form the first cured layer, and the printer 806B and the second curing device (not shown) may be used to print and cure the second immobilization feature to form the second cured layer on top of the first cured layer.

The curing process performed by the curing devices 820 may be performed by heating the printed immobilization feature to a curing temperature or exposing the immobilization feature to one or more forms of electromagnetic radiation or electron beam curing. In one example, the curing process may be performed by exposing the immobilization feature to radiation generated by an electromagnetic radiation source, such as a visible light source, an ultraviolet light source, and x-ray source, or other type of electromagnetic wave source that is disposed within the curing devices 820. In other implementations, other forms of energy may be used for curing.

The additive manufacturing process offers a convenient and highly controllable process for producing immobilization structures 106 having a plurality of immobilization features for securing the dies 102 to the substrate 100. Each immobilization structure 106 may have discrete immobilization features 108 at least partially surrounding the die 102, as discussed for example with respect to FIGS. 1B and 2A-2B. Each immobilization structure 106 may be formed from different materials and/or different compositions of materials.

FIG. 8B is a schematic cross-sectional view of the printing station 800 and dies 102-1, 102-2, 102-3 disposed on the substrate 100 during the immobilization process. The printing station 800, as shown in FIG. 8B, includes two printers 806A and 806B that are used to sequentially form a plurality of immobilization features. During processing the printer 806A is configured to deliver droplets “A” to the substrate 100 in a layer by layer process. The printer 806A is also configured to deliver droplets “B” in a similar manner. As shown in FIG. 8B, immobilization features 108 are being formed adjacent each die 102. The printer 806A may deliver a liquid composition in the form of droplets A to form a first immobilization feature 846 on the contact layer 104 and the substrate 100. The droplets A are moved downstream so that the curing device 820 is disposed so as to direct electromagnetic radiation onto the droplets A. The curing device is configured to expose the droplets A of the first immobilization feature 846 to a sufficient amount of radiation to cure the first immobilization feature 846. The first immobilization feature 846 is depicted in FIG. 8B as being formed by a first cured layer for each of the immobilization features 108 disposed adjacent and used to secure dies 102-1, 102-2, 102-3 in position on the substrate 100.

A second immobilization feature 848 is deposited over the first immobilization feature 846 that has been previously cured by the curing device 820. The second immobilization feature 848 is formed over the first immobilization feature 846 which has been processed by the curing device 820 to form the first cured layer that is disposed downstream from the printer 806A in the immobilization process. For example, droplets from the printer 806A are dispensed on the first cured layer forming the first immobilization feature 846. The droplets form a second uncured layer forming the second immobilization feature 848 and disposed on the first immobilization feature 846. The substrate 100 moves downstream with respect to printer 806A to position the uncured second layer forming the second immobilization feature 848 to a position proximate the curing device 820. The curing device 820 generates electromagnetic radiation that cures the uncured second layer forming the second immobilization feature 848. In some implementations, portions of the second immobilization feature 848 may be simultaneously processed by the curing device 820 while one or more of the printers 806A and 806B are depositing droplets “A” and/or “B” onto the top surface of the previously formed first immobilization feature 846.

Referring to FIG. 8B, the die 102-1 has immobilization features 108 that are formed by the first immobilization feature 846 and the second immobilization feature 848. The immobilization features 108 are shown downstream of the curing device 820, and are shown as having been cured so that the first cured layer forms the first immobilization feature 846 and the second cured layer forms the second immobilization feature 848.

The die 102-2 shows one of its immobilization features 108 as being upstream of the curing device 820. The upstream immobilization feature 108A shows the first immobilization feature 846 as being formed by a first cured layer, and shows the second immobilization feature 848 being formed from the second uncured layer. The second cured layer is being formed by uncured droplets 848A dispensed from the printer 806A. The uncured droplets 848A may form the second immobilization feature 848 prior to curing. The uncured droplets 848A are disposed adjacent the die 102-2 and upstream of the curing device 820. The uncured droplets 848A are deposited on the first immobilization feature 846 previously formed by the printer 806A and cured by the curing device 820.

The die 102-3, shown in FIG. 8B, includes an immobilization feature 108B and an immobilization feature 108C. The immobilization feature 108B is upstream of the curing device 820 and has uncured droplets 848A that are forming the second uncured layer. When the immobilization feature 108B is moved downstream, the uncured droplets 848A will be cured by the curing device 820, as discussed above with respect to immobilization feature 108A. The immobilization feature 108C is shown in FIG. 8B as being upstream of both the printer 806A and the curing device 820. The immobilization feature 108C, at this stage of the immobilization process, includes a first immobilization feature 846 formed by a first cured layer. As the die 102-3 moves downstream, with respect to the printing station 800 and curing device 820, the second immobilization feature 848 of the immobilization feature 108C will be formed as discussed with respect to dies 102-1 and 102-2.

The materials used to form portions of the immobilization structure 106 having a plurality of immobilization features 108 may be formed from at least one ink jettable pre-polymer composition that may be a mixture of functional polymers, functional oligomers, reactive diluents, and curing agents to achieve the desired properties of the immobilization structures 106. In general, the pre-polymer inks or compositions may be processed after being deposited by use of any suitable manner including exposure or contact with radiation or thermal energy, with or without a curing agent or chemical initiator. In general, the deposited material can be exposed to electromagnetic radiation, which may include ultraviolet radiation (UV), gamma radiation, X-ray radiation, visible radiation, IR radiation, and microwave radiation and also accelerated electrons and ion beams may be used to initiate polymerization reactions. For the purposes of this disclosure, the method of cure or the use of additives to aid the polymerization, such as sensitizers, initiators, and/or curing agents, such as through cure agents or oxygen inhibitors, are not restricted.

In one embodiment, the immobilization structures 106 may be formed from the sequential deposition and post deposition processing of at least one radiation curable resin precursor composition, wherein the compositions contain functional polymers, functional oligomers, monomers, and/or reactive diluents that have unsaturated chemical moieties or groups, including but not restricted to: vinyl groups, acrylic groups, methacrylic groups, allyl groups, and acetylene groups. During the immobilization process, the unsaturated groups may undergo free radical polymerization when exposed to radiation, such as UV radiation, in the presence of a curing agent, such as a free radical generating photoinitiator.

In some implementations, the immobilization material is an inkjet printing formulation material for dies that may be selected from a group consisting of acrylate, methacrylate, and/or acrylamide, and/or epoxide, and/or oxetane monomers, oligomers, polymers, blocked copolymers, and photoinitiators. The mold layer comprises a molding material that is selected from a group consisting of an epoxy material. Each of the immobilization features is separately cured before another immobilization feature is formed on top. The immobilization material and the electromagnetic radiation applied to each immobilization feature is selected so that the uncured immobilization feature is cured so as to be converted to solid polyacrylate materials, via photo-induced free radical polymerization within a selected curing period. In some implementations, the selected curing period may be in the range of 0.5 to 1.5 seconds. Each immobilization feature functions to help immobilize the dies on the substrate at room temperature, such as a temperature range of about 22 to about 25 degrees Celsius.

In some implementations, the size of dispensed droplets “A”, “B” may be from about 10 to about 200 microns, such as about 50 to about 70 microns. Depending on the surface energy (dynes) of the substrate 100 or polymer material of the immobilization feature that the droplet is dispensed over and upon, the uncured droplet may spread on and across the surface to a size of between about 10 and about 500 microns, such as between about 50 and about 200 microns. In one example, the height of such a droplet may be from about 5 to about 100 microns, depending on such factors as surface energy, wetting, and/or resin precursor composition which may include other additives, such as flow agents, thickening agents, and surfactants.

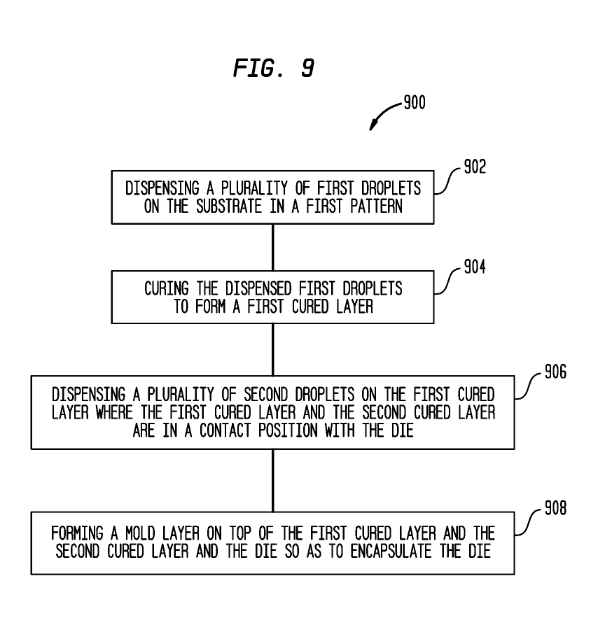

Referring to FIG. 9, a flow chart for the encapsulation process 900, according to one implementation, is shown. The encapsulation process 900 provides a method for encapsulating a substrate. The encapsulation process 900 includes sequentially forming a plurality of immobilization features in a selected pattern on the substrate. The substrate has a die formed on the substrate and the plurality of immobilization features formed on the substrate is in a contact position with the die. The encapsulation process 900 includes dispensing a plurality of first droplets on the substrate in the first pattern, at block 902; curing the dispensed first droplets to form a first cured layer, at block 904. The encapsulation process 900 further includes dispensing a plurality of second droplets on the first cured layer where the first cured layer and the second cured layer are in a contact position with the die, at block 906; and curing the dispensed second droplets to form a second cured layer. A first immobilization feature is formed by the first cured layer and a second immobilization feature is formed by the second cured layer. The encapsulation process 900 further includes forming a mold layer on top of the first cured layer and the second cured layer and the die so as to encapsulate the die, at block 908.

While FIG. 9 shows one example of a method, other alternatives are also contemplated. In one example, it is contemplated that a die may be positioned on a substrate prior to deposition of immobilization features. In another example, it is contemplated that a die may be positioned on or in contact with immobilization features after deposition of immobilization features.

While the foregoing is directed to examples of the present disclosure, other and further examples of the disclosure may be devised without departing from the basic scope thereof, and the scope thereof is determined by the claims that follow.

What is claimed is:

1. A method for packaging a die on a substrate, comprising:
forming one or more immobilization features in a selected pattern on the substrate by inkjet printing;
positioning a die in contact with the one or more immobilization features and the substrate;
curing the one or more immobilization features; and
forming a mold layer on top of the cured one or more immobilization features and the die so as to encapsulate the die.

2. The method of claim 1, wherein forming a mold layer on the die comprises:
dispensing a molding material on top of the one or more immobilization features; and
applying pressure and heat to the dispensed molding material.

3. The method of claim 1, wherein the die and the one or more immobilization features are formed on a contact layer disposed on the substrate.

4. The method of claim 1, wherein the die has a perimeter and the immobilization structure is disposed at the perimeter.

5. The method of claim 4, wherein the one or more immobilization features are spaced apart from one another.

6. The method of claim 5, wherein the die has a plurality of corners, and wherein the one or more immobilization features comprises a first immobilization feature disposed at one of the plurality of corners and a second immobilization feature disposed at another of the plurality of corners.

7. The method of claim 5, wherein the die has a plurality of sides, wherein the one or more immobilization features comprises a first immobilization feature disposed at one of the plurality of sides and a second immobilization feature disposed at another of the plurality of sides.

8. The method of claim 7, wherein the one or more immobilization features comprise an immobilization material that is selected from a group consisting of acrylate, methacrylate, acrylamide, epoxide, oxetane monomers, oligomers, polymers, blocked copolymers, and photoinitiators, and wherein the mold layer comprises a molding material that is selected from a group consisting of an epoxy material.

9. The method of claim 7, further comprising removing the contact layer and the substrate from the die and the one or more immobilization features after forming the mold layer.

10. The method of claim 7, wherein each of the one or more immobilization features are formed by first droplets and second droplets in a side-by-side position abutting one another.

11. The method of claim 1, wherein the one or more immobilization features is a single feature disposed fully around the perimeter of the die.

12. The method of claim 1, wherein curing the one or more immobilization features comprises applying electromagnetic radiation to the one or more immobilization features.

13. The method of claim 12, wherein the one or more immobilization features is a single feature disposed fully around the perimeter of the die.

14. A method for packaging a plurality of die on a substrate, comprising:
forming a plurality of immobilization structures on the substrate, wherein each of the plurality of immobilization structures is in a contact position with at least one of the plurality of dies, forming each of the plurality of immobilization structures comprises:
forming a first immobilization feature on the substrate, wherein forming the first immobilization feature comprises:
dispensing a plurality of first droplets on the substrate;
curing the dispensed first droplets to form a first cured layer;
forming a second immobilization feature on a surface of the first cured layer, wherein forming the second immobilization feature comprises:
dispensing a plurality of second droplets on the first cured layer; and
curing the dispensed second droplets to form a second cured layer.

15. The method of claim 14, further comprising:
forming a mold layer on top of the plurality of immobilization structures.

16. The method of claim 14, wherein the curing the comprises applying electromagnetic radiation to the one or more immobilization features.

17. The method of claim 16, wherein the first immobilization structure and the second immobilization structure are separate from one another.

18. The method of claim 16, wherein the first immobilization structure and the second immobilization structure are in contact with one another.

19. A method for packaging a die on a substrate, comprising:
positioning a die in contact with the substrate;
forming one or more immobilization features in a selected pattern on the substrate and in contact with the die, the one or more immobilization features formed by inkjet printing;
curing the one or more immobilization features; and
forming a mold layer on top of the cured one or immobilization features and the die.

20. The method of claim 19, wherein the one or more immobilization features comprise an immobilization material that is selected from a group consisting of acrylate, methacrylate, acrylamide, epoxide, oxetane monomers, oligomers, polymers, blocked copolymers, and photoinitiators.
